(19) United States
(12) Patent Application Publication
(10) Pub. No.: US 2017/0184670 A1
(43) Pub. Date: Jun. 29, 2017

(54) TEST CIRCUIT BOARD ADAPTED TO BE USED ON SERIAL ADVANCED TECHNOLOGY ATTACHMENT CONNECTOR

(71) Applicants: Inventec (Pudong) Technology Corporation, Shanghai (CN); Inventec Corporation, Taipei City (TW)

(72) Inventors: Ping Song, Shanghai (CN); Chang Qing Mu, Shanghai (CN); Xiao Qian Li, Shanghai (CN)

(21) Appl. No.: 15/073,576

(22) Filed: Mar. 17, 2016

(30) Foreign Application Priority Data
Dec. 24, 2015 (CN) 201510991265.7

(51) Int. Cl. G01R 31/3177; G01R 31/317

(52) U.S. Cl. CPC G01R 31/3177; G01R 31/31723

(57) ABSTRACT

A test circuit board adapted to be used on SATA connector is provided. Two test circuit boards can be seriously connected with each other through a first JTAG connection interface and a second JTAG connection interface. Therefore, the efficiency of reducing TAPs of TAP controller and providing test signal coverage of all of test signals may be achieved.

### CROSS-REFERENCE TO RELATED APPLICATION

This application claims the benefit of Chinese Patent Application No. 201510991265.7, filed Dec. 24, 2015.

### BACKGROUND OF THE RELATED ART

Technical Field

The present invention relates to a circuit board, and particularly to a circuit board adapted to be used on serial advanced technology attachment connector (SATA) where a first joint test activity group (JTAG) connection interface and a second JTAG connection interface are provided to form an in-series connection between test circuit boards.

Related Art

For the currently available the test technologies regarding a serial advanced technology attachment (SATA) connector in a board to be tested, only a single test circuit board is tested in most cases, and only a single SATA connector may be tested. In this case, the issue of absence of a test signal coverage is generally arisen, lending to an unfavorable effect on the test in a production process.

In view of the above, it may be known that there has long been existed in the prior art of the absence of the test signal coverage on the SATA connector in the board to be tested. Therefore, there is quite a need to set forth an improvement means to settle down this problem.

### SUMMARY

In view of the issues of absence of the test signal overage of the serial advanced technology attachment (SATA) connector in the board to be tested in the prior art, the present invention provides a test circuit board suitable to be used on SATA connector.

According to the present invention, the test circuit board adapted to be used on SATA connector comprises the test circuit board, further comprising a SATA connection interface, forming an electrical connection being inserted into a SATA connector; a first joint test action group (JTAG) connection interface, connected electrically to a test access port (TAP) controller or connected electrically to a second JTAG connection interface of another test circuit board to form an in-series connection with the another test circuit board; a second JTAG connection interface, connected electrically to the first JTAG connection interface of the another test circuit board; a JTAG signal processing chip, connected electrically to the first and second JTAG respectively, to increase a stability of a JTAG signal of the first and second JTAGs respectively; at least a JTAG control chip, connected electrically to the JTAG processing chip, to detect a plurality of pins of the SATA connector, control a state of the SATA connector and simulate an Inter-Integrated Circuit (IIC) of the SATA connector; and a voltage conversion chip, providing a work voltage required by the JTAG signal processing chip and the JTAG control chip respectively, through the SATA connector by acquiring a power supply.

The test circuit board of the present invention has the difference as compared to the prior art that the first and second JTAG connection interfaces of the test circuit board may form the in-series connection there between to reduce a required number of TAP ports in the TAP controller, and the test circuit board provides a test signal coverage on all the test signals, facilitate a use of a production line, to further reduce a cost of the test circuit board.

By using the above technical means, the present invention may achieve in the technical efficacies of a reduced required TAP number in the TAP controller and a test signal coverage on all the test signals.

### BRIEF DESCRIPTION OF THE DRAWINGS

The present invention will be better understood from the following detailed descriptions of the preferred embodiments according to the present invention, taken in conjunction with the accompanying drawings, in which:

FIG. 1 is a schematic diagram of an architecture of a test circuit board adapted to be used on SATA connector according to the present invention; and

FIG. 2 is a schematic diagram of an architecture of the test circuit board adapted to be used on SATA connector in a test process according to the present invention.

### DETAILED DESCRIPTION

The present invention will be apparent from the following detailed description, The present invention will be apparent from the following detailed description, which proceeds with reference to the accompanying drawings, wherein the same references relate to the same elements.

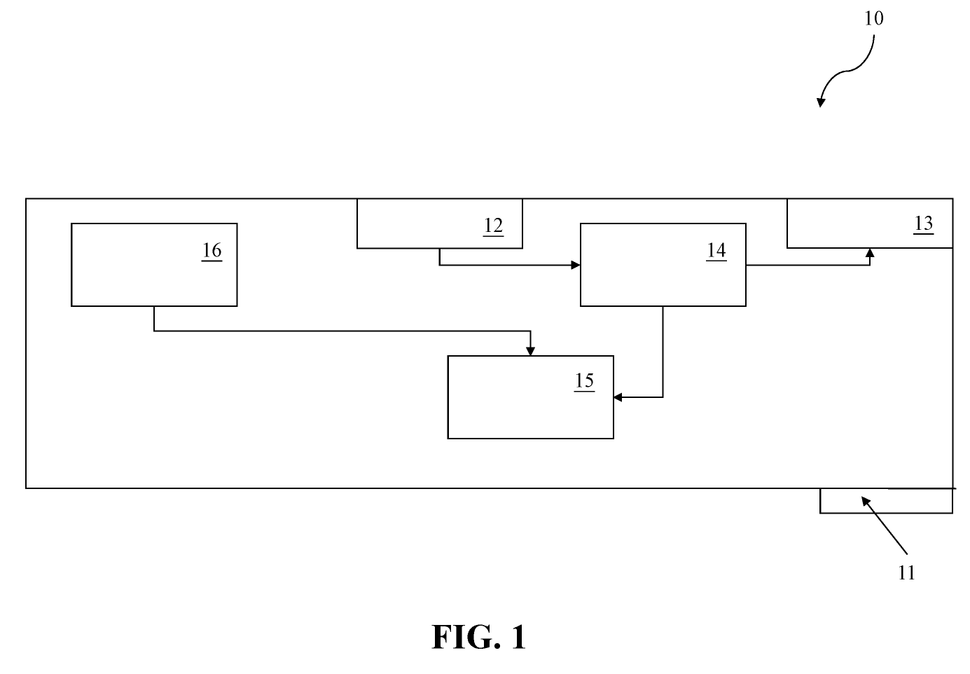

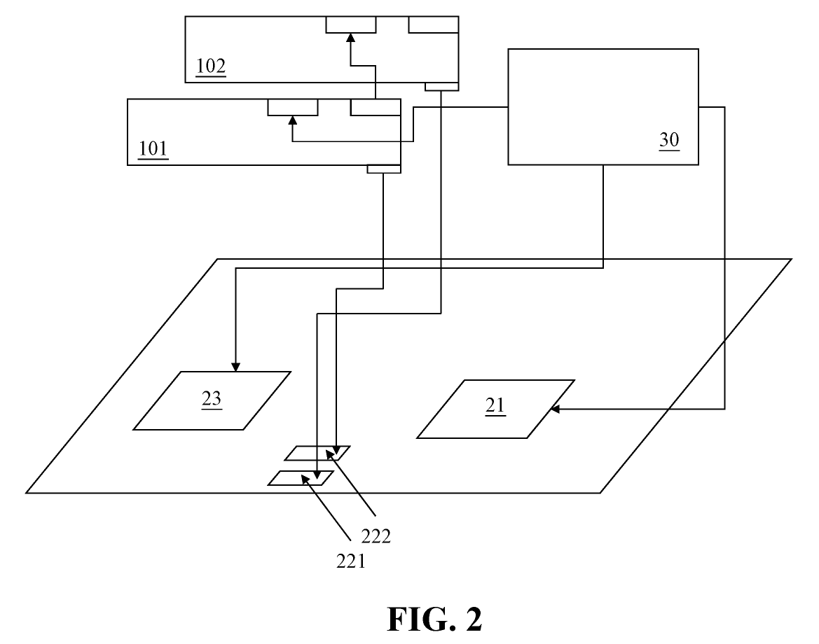

In the following, a test circuit board adapted to be used on serial advanced technology attachment (SATA) connector disclosed in the present invention will be described with reference to FIG. 1 and FIG. 2. FIG. 1 is a schematic diagram of an architecture of a test circuit board adapted to be used on SATA connector according to the present invention. FIG. 2 is a schematic diagram of an architecture of the test circuit board adapted to be used on SATA connector in a test process according to the present invention.

The test circuit board 10 further comprises a SATA connection interface 11, a first joint test action group (JTAG) connection interface 12, a second JTAG connection interface 13, JTAG signal processing chip 14, at least a JTAG control chip 15, at least an analog-to-digital converter (ADC) chip 16, a switch chip 17 and a voltage conversion chip 16.

A board to be tested 20 further comprises a central processing unit (CPU) 21, a plurality of SATA connectors 22 and a complex programmable logic device (CPLD) 23.

The SATA connection interface 11 of the test circuit board 10 is used to insert the test circuit board 10 onto the SATA connector 22 of the board to be tested 20, to form an electrical connection between the test circuit board 10 and the board to be tested 20. Each of the SATA connectors 22 may be inserted onto one test circuit board 10.

The first JTAG connection interface 12 of the test circuit board 10 is used to connect electrically to a test access port (TAP) controller 30, or the first JTAG connection interface 12 of the test circuit board 10 is used to connect electrically to the second JTAG connection interface 13 of another test circuit board 10, so that the test circuit board 10 may be connected in series with another test circuit board.

Specifically, the board to be tested 20 has a first SATA connector 221 and a second SATA connector 222. The first test circuit board 101 is inserted onto a first SATA connector 221 of the board to be tested 20. The second test circuit board 102 is inserted onto the second SATA connector 222. The first JTAG connection interface 12 of the first test circuit board 101 is connected electrically to the TAP controller 30. The second JTAG connection interface 13 of the first test circuit board 101 is connected electrically to the first JTAG connection interface 12 of the second test circuit board 102, so that an in-series connection may be formed between the first test circuit board 101 and the second test circuit board 102. However, this embodiment is merely an example, without limiting the present invention.

The JTAG signal processing chip 14 of test circuit board 10 is connected electrically to the first JTAG connection interface 12 and the second JTAG connection interface 13 of the test board 10. The JTAG signal processing chip 14 of the test circuit board 10 is used to increase a stability of a JTAG signal transmitted by the first JTAG connection interface 12 of the test circuit board 10 and the second JTAG connection interface 13 of the test circuit board 10.

The board to be tested 20 of the CPU 21 is used to detect the test circuit board 10 in a boundary scan. The board to be tested 20 has a complex programmable logic device (CPLD) is used to control a power state of the board to be tested 20.

The TAP controller 30 is connected electrically to the CPU 21 of the board to be tested 20 and the CPLD 23 of the board to be tested 20. Further, the TAP controller 30 is used to control the CPLD 23 of the board to be tested 20, to control a state of a power supply. The test TAP controller 30 is also used to control the CPU 21 of the board to be tested 20 and the CPLD 23 of the board to be tested 20 to work in a boundary scan mode. And, the test TAP controller 30 controls the board to be tested 10 through the first JTAG connection interface 12 to work in a boundary scan mode.

The JTAG control chip 15 of the test circuit board 10 and the JTAG signal processing chip 14 of the test circuit board 10 are connected electrically to each other, and the JTAG control chip test circuit board 15 of the test circuit board 10 is used to detect the pins of the SATA connector 22 of the board to be tested 20.

Specifically, a differential signal in the SATA connector 22 of the to be tested board 20 is connected to the JTAG control chip 15 of the to be tested board 10. The detection for the signal Tx of the SATA connector 22 of the board to be tested 20 is performed by sending out a high speed signal by a platform controller hub (PCH) of the board to be tested 20. Then, the JTAG control chip 15 of the test circuit board 10 detects the signal Tx. The detection for the signal Rx of the SATA connector 22 of the board to be tested 20 is performed by sending out a high speed signal by the JTAG control chip 15 of the test circuit board 10. Then, the PCH of the board to be tested 10 detects the signal Tx. Signal GND of the SATA connector 22 of the board to be tested 20 is connected to the I/O pins of the JTAG control chip 15 of the board to be tested. The JTAG control chip 15 of the board to be tested 20. By reading a state of the signal GND, the JTAG control chip 15 of the board to be tested 10 may detect a connection state of the signal GND.

The voltage conversion chip 16 of the test circuit board 10 is used to acquire a power supply through the SATA connector 22 of the test circuit board 10 and convert the power, so that a work voltage may be provided to the JTAG signal processing chip 14, the JTAG control chip 15, the ADC switch chip 16 and the switch chip 17 of the test circuit board 10.

The TAP controller 30 detects and perform a state control regarding the pins of the ATA connector 22 of the board to be tested 20 through the JTAG control chip 14 of the board to be tested 10 when the CPLD 23, when the CPU 21 of the board to be tested 20 and the board to be tested 10 operate in the boundary scan mode.

In summary, the test circuit board of the present invention has the difference as compared to the prior art that the first and second JTAG connection interfaces of the test circuit board may form the in-series connection there between to reduce a required number of TAP ports in the TAP controller, and the test circuit board provides a test signal coverage on all the test signals, facilitate a use of a production line, to further reduce a cost of the test circuit board.

By using the technical means of the present invention, the issues long encountered in the prior art of absence of the test signal overage of the SATA connector in the board to be tested may be overcome, and the technical efficacies of a reduced required TAP number in the TAP controller and a test signal coverage on all the test signals may also be achieved.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A test circuit board adapted to be used on serial advanced technology attachment (SATA) connector, comprising:
the test circuit board, further comprising:
a SATA connection interface, forming an electrical connection being inserted into a SATA connector;
a first joint test action group (JTAG) connection interface, connected electrically to a test access port (TAP) controller or connected electrically to a second JTAG connection interface of another test circuit board to form an in-series connection with the another test circuit board;
a second JTAG connection interface, connected electrically to the first JTAG connection interface of the another test circuit board;
a JTAG signal processing chip, connected electrically to the first and second JTAG respectively, to increase a stability of a JTAG signal of the first and second JTAGs respectively;
at least a JTAG control chip, connected electrically to the JTAG processing chip, to detect a plurality of pins of the SATA connector, control a state of the SATA connector and simulate an Inter-Integrated Circuit (IIC) of the SATA connector; and
a voltage conversion chip, providing a work voltage required by the JTAG signal processing chip and the JTAG control chip respectively, through the SATA connector by acquiring a power supply.

2. The test circuit board adapted to be used on SATA connector as claimed in claim 1, further comprising a board to be tested, comprising:
a central processing unit (CPU), providing a boundary scan mode to detect the test circuit board; and
a plurality of SATA connectors, providing an insert connection of the test circuit board; and
a complex programmable logic device (CPLD), controlling a power state of the board to be tested.

3. The test circuit board adapted to be used on SATA connector as claimed in claim 3, wherein the TAP controller is connected electrically to the CPU, the CPLD and the first JTAG connection interface respectively.

4. The test circuit board adapted to be used on SATA connector as claimed in claim 3, wherein the TAP controller is used to control the CPLD to control a power supply state of the board to be tested.

5. The test circuit board adapted to be used on SATA connector as claimed in claim 3, wherein the TAP controller is used to control the CPLD and the CPU to have a boundary scan mode.

6. The test circuit board adapted to be used on SATA connector as claimed in claim 1, wherein the TAP controller is used to control the test circuit board to have the boundary scan mode.

7. The test circuit board adapted to be used on SATA connector as claimed in claim 3, wherein the TAP controller is used to detect the plurality of pins of the SATA connector, control a state of the SATA connector, simulate the IIC of the SATA connector, detect the voltage of the plurality of pins of the SATA connector, and detect the particular signal of the plurality of pins of the SATA connector at the CPU, the CPLD and the test circuit board have the boundary scan mode.
